(19) United States
(12) Patent Application Publication
(10) Pub. No.: US 2011/0249406 A1
(43) Pub. Date: Oct. 13, 2011

(54) HEAT DISSIPATION SYSTEM FOR ELECTRICAL COMPONENTS

(75) Inventor: Peter Scott Andrews, Durham, NC (US)

(73) Assignee: LEDAdventures LLC

(21) Appl. No.: 13/165,162

(22) Filed: Jun. 21, 2011

Related U.S. Application Data
(63) Continuation-in-part of application No. 12/488,546, filed on Jun. 20, 2009.

(51) Int. Cl. H05K 7/20

(52) U.S. Cl. 361/704

(57) ABSTRACT

The present invention relates to a system for dissipating heat for one or more electrical components. A first solid heat dissipation structure is connected to a heatsink connection pad of the component while a second heat dissipation structure surrounds the first structure but not in contact with the connection pad to thermally regulate the heat of the electrical component.

This application is a continuation-in-part of U.S. non-provisional application Ser. No. 12/488,546, filed on Jun. 20, 2009 and is included herein in its entirety by reference.

### COPYRIGHT NOTICE

A portion of the disclosure of this patent contains material that is subject to copyright protection. The copyright owner has no objection to the reproduction by anyone of the patent document or the patent disclosure as it appears in the Patent and Trademark Office patent files or records, but otherwise reserves all copyright rights whatsoever.

### BACKGROUND OF THE INVENTION

1. Field of the Invention

The present invention relates to electrical components and methods of dissipating heat for electrical components, in particular, to structures and devices for heat dissipation for electrical components, such as high power Light Emitting Diode (LED) components.

2. Description of Related Art

Electrical devices and components, such as power components and high-power LEDs, have a high power consumption per area generating a significant amount of heat in a small area which, if not managed, can degrade the performance of the device and/or system, and can provide localized hot spots that are too hot to touch.

The necessity for management of heat to preserve performance of electrical devices is widely known. LED components are particularly sensitive in that their optical output or efficiency is directly related to the junction temperature of the LED device. Power components, used for power conditioning, also generate a significant amount of heat and many of them come packaged with built-in heatsinks for thermal dissipation. There is a large industry surrounding varieties of heatsinks, thermal pads, and thermal compounds for enhancing conduction to heat dissipating structures for power conditioning, heat generating, or heat sensitive components.

In order to address a growing market segment for lighting-class-products and other niche markets, the current trend in LED components is to increase the Lumens that can be achieved from a single package. This increase is accomplished by increasing the rated power that can be input and efficiently converted to light. Thus, high-power-LED components are requiring more rigorous heat management than ever before.

For the conduction of heat away from a high-power LED component, the most common methods are the use of thermal-vias (non-solid holes) within a Printed Circuit Board or Printed Wiring Board (PCB/PWB) to conduct heat to bottom side metal, or the use of a Metal Core Printed Circuit Board or Metal Core Printed Wiring Board (MCPCB/PWB) which also offers good thermal conduction from the LED component. The PCB/PWB or MCPCB/PWB is then attached, usually mechanically with the aid of thermal conductive grease or thermal conductive pad, to a large heat-sink or to a forced convection-fin system to dissipate the heat.

PCB/PWB with thermal vias have a disadvantage in that the area of each via is constrained requiring multiple thermal vias to be used to maximize the area of increased heat transfer. Also, the thermal conductivity of plated-through or filled thermal-vias is generally not as good as “melted” metals. A further loss of conduction efficiency is incurred by the interface from the back of the PCB/PWB to the heat dissipating component.

The MCPCB/PWB has a disadvantage in that there is a dielectric layer between the metal core and printed circuit traces. There has been much work to increase the heat transfer to the metal core as efficiently as possible by careful choice of dielectric compounds and carefully controlling thickness, however, electrically-insulating materials have generally poor thermal conductivity. When comparing the thermal resistance of a thin solder layer directly bonded to Copper, versus a thin solder layer bonded to a thin Copper trace, which is bonded to a dielectric layer, which is bonded to a metal core (typically Aluminum), the advantages in thermal resistance of the former are apparent.

When multiple electrical components are designed on a single board, the thermal constraints frequently limit the design options. Also as with PCB/PWBs, the transfer of heat across the interface from the MCPCB/PWB to the heat-sink (or heat dissipating device) is critical for thermal efficiency. This interface is typically by mechanical attachment with the aid of thermal conductive grease or thermal conductive pad to maximize surface area contact.

In yet other embodiments on the market today, heat pipes are used to transfer heat away through evaporative/condensing cycling to heat dissipation surfaces. In other embodiments, active cooling is employed to manage heat at the LED or heat generating device by using Thermo-Electric Cooling devices to control heat flow and dissipation. Both of these are relatively expensive options for heat dissipation.

LED packaged components are rated with a thermal resistance in degrees Celsius per Watt, C/W. This is generally referenced as the thermal resistance from the LED junction temperature, which affects LED performance, to the solder point on the LED component. The amount of Lumens over time that a consumer can get from a High-Power-LED-Component (HPLEDCOMP) at a given power input is directly related to how well the thermal resistance components are managed during assembly of the system. The current state of the art has limitations in the efficiency of thermal transfer, or has limitations in how the supporting system can be designed to keep thermal resistance low, or incurs a higher cost to achieve high efficiency in heat removal.

### BRIEF SUMMARY OF THE INVENTION

The present invention relates to the discovery that positioning a first solid heat dissipation structure in contact with the heatsink connection pad and surrounding the first structure with a second solid heat dissipation structure not in contact with the heatsink connection pad solves many of the above identified problems with heat dissipation for LED's and other electrical components.

Accordingly, in one embodiment of the present invention there is an electrical component having a heatsink connection pad which has a selected width in direct contact with the electrical component, which has electrical leads from a power supply to the component to supply the component electrical power and having a heat dissipation system comprising:
a) a first solid heat dissipation structure, thermally coupled directly to the connection pad having a length greater than the connection pad width; and
b) a second solid heat dissipation structure surrounding and thermally coupled to the first structure for a distance greater than the width of the connection pad but which is not coupled to the connection pad and positioned the conduct heat energy to an ambient environment.

### BRIEF DESCRIPTION OF THE DRAWINGS

FIG. 1 is a top view of an embodiment of the present invention showing the relationship of the first and second dissipation structures.

FIG. 2A is side cross sectional view of the embodiment of FIG. 1.

FIG. 2B is a side cross sectional view of an alternate embodiment of the present invention.

FIG. 3A is a top view of an embodiment with a printed wiring board included.

FIG. 3B is a side cross sectional view of the embodiment of FIG. 3A.

FIG. 4A is a top view of an embodiment of the invention where the electrical component is multiple LEDs.

FIG. 4B is a side cross sectional view of the embodiment of FIG. 4A.

FIG. 5A is a top view of an embodiment of the invention where the electrical component is multiple LEDs.

FIG. 5B is a side cross sectional view of the embodiment of FIG. 5A.

FIG. 6 is a flowchart of the method of utilizing the system of the present invention.

### DETAILED DESCRIPTION OF THE INVENTION

While this invention is susceptible to embodiment in many different forms, there is shown in the drawings and will herein be described in detail specific embodiments, with the understanding that the present disclosure of such embodiments is to be considered as an example of the principles and not intended to limit the invention to the specific embodiments shown and described. In the description below, like reference numerals are used to describe the same, similar or corresponding parts in the several views of the drawings. This detailed description defines the meaning of the terms used herein and specifically describes embodiments in order for those skilled in the art to practice the invention.

The terms “a” or “an”, as used herein, are defined as one or as more than one. The term “plurality”, as used herein, is defined as two or as more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically.

Reference throughout this document to “one embodiment”, “certain embodiments”, and “an embodiment” or similar terms means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner in one or more embodiments without limitation.

The term “or” as used herein is to be interpreted as an inclusive or meaning any one or any combination. Therefore, “A, B or C” means any of the following: “A; B; C; A and B; A and C; B and C; A, B and C”. An exception to this definition will occur only when a combination of elements, functions, steps or acts are in some way inherently mutually exclusive.

The drawings featured in the figures are for the purpose of illustrating certain convenient embodiments of the present invention, and are not to be considered as limitation thereto. Term “means” preceding a present participle of an operation indicates a desired function for which there is one or more embodiments, i.e., one or more methods, devices, or apparatuses for achieving the desired function and that one skilled in the art could select from these or their equivalent in view of the disclosure herein and use of the term “means” is not intended to be limiting.

Those skilled in the art to which the present invention pertains may make modifications resulting in other embodiments employing principles of the present invention without departing from its spirit or characteristics, particularly upon considering the foregoing teachings. Accordingly, the described embodiments are to be considered in all respects only as illustrative, and not restrictive, and the scope of the present invention is, therefore, indicated by the appended claims rather than by the foregoing description or drawings. Consequently, while the present invention has been described with reference to particular embodiments, modifications of structure, sequence, materials and the like apparent to those skilled in the art still fall within the scope of the invention as claimed by the applicant.

It will be understood that when an element such as a layer, region, or body is referred to as being “on” another element, it can be directly on the other element or intervening elements may also be present. It will be understood that if part of an element, such as a surface, is referred to as “inner”, it is farther from the outside of the system than other parts of the element. Furthermore, relative terms such as “beneath” or “overlies” may be used herein to describe a relationship of one layer or region to another layer or region relative to a substrate or base layer as illustrated in the figures. It will be understood that these terms are intended to encompass different orientations of the system in addition to the orientation depicted in the figures. Finally, the term “directly” means that there are no intervening elements. As used herein, the term “and/or” includes any and all combinations of one or more of the associated listed items.

It will be understood that, although the terms first, primary, second, secondary, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the invention are described herein with reference to cross-sectional, perspective, and/or plan view illustrations that are schematic illustrations of idealized embodiments of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, a region illustrated or described as a rectangle will, typically, have rounded or curved features due to normal manufacturing tolerances. Thus, the regions illustrated in the figures are schematic in nature and their shapes are not intended to illustrate the precise shape of a region of a device and not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Some embodiments of the present invention relate to upper-level packaging, or fixture, of electrical components. As used herein, the term “electrical component” may include an integrated circuit (IC) device, an application specific integrated circuit (ASIC), a power field effect transmitter (FET), a Light Emitting Diode (LED), laser diode, and/or other semiconductor components or devices which include one or more semiconductor layers, which may include silicon, silicon carbide, gallium nitride, and/or other semiconductor materials. For example, the semiconductor light emitting device may be gallium nitride-based LED sold as a surface mount high-power component such as those manufactured and sold by Cree, Inc. of Durham, N.C. Other examples of semiconductor devices could be high power LED components from Lumileds, Osram, Nichia, etc. which are generally considered lighting class products.

Solder is commonly used to make electrical and thermal connections for high-power LED components. Some embodiments of the present invention use solder to make the thermal connection between the LED component and the primary heat conductor as well as make the electrical connections to wire or PCB/PWB. Solder is a general category consisting of various alloys that can be reflowed to form metallurgical bonds between various metals. Common solders that would be used for this type of application would be high temperature solders such as gold-tin eutectic solders (80/20 Au/Sn), lead-free solders such as tin-silver-copper alloys (97/2.5/0.5 Sn/Ag/Cu), or tin-lead alloys (63/37 Sn/Pb). For the purposes of these embodiments, the materials or structures which are referred to as being solder attached, are assumed to be able to be wetted by solder, or to have a plating such that the plating is able to be wetted by solder, such that a metallurgical bond is formed assuring good electrical or thermal conductive properties.

Some embodiments of the present invention can use means other than solder to make electrical and thermal connections. Methods such as electrically conductive adhesive (Ag-filled epoxy is common), conductive inks, mechanical contact, etc. are used for electrical connections. Thermal connections are commonly made with thermal-compound (commonly known as thermal grease), mechanical contact, thermal pads, etc. to achieve acceptable thermal conductivity. In general, solder provides the most economical and best method for electrical and thermal connections, so following discussions will reference solder, however, it is to be understood that this is not limiting other methods to make electrical or thermal connections.

By the same token, some embodiments of the present invention reference metallurgical bonding/joining which include methods of brazing or welding. Brazing is commonly defined as using a filler metal or alloy and higher temperatures than soldering to form a metallurgical bond. Post processes, such as annealing, are commonly used after brazing to increase strength of the bond. Welding is also a common method where metal is coalesced to form a bond. Many different methods and material combinations can be used to form welded joints and these are considered commonly known to people skilled in the art.

Heat energy is generally referred to as being dissipated to ambient. For the purposes of this invention, ambient is a general term that represents a significantly larger thermal mass at a lower energy state. This is generally taken as the surrounding atmosphere, or large pool of water, or convective air stream, much larger metal structure, or many other cases which would be understood by those skilled in the art of heat dissipation. For purposes of this discussion, ambient is understood to be a relatively infinite heatsink for heat energy.

In some embodiments of the invention, the terms “rod” or “bar” imply a circular or square cross-sectional shape. These shapes are generally commonly available and are used for ease of explanation. The terms rod and bar are not meant to be exclusive but are meant to refer to any physical volume/shape that extends significantly more in one dimension than the other two dimensions.

Electrical components of the present invention are fitted in direct contact (usually on the underside) with a heatsink connection pad which is a metallic or other structure for removing heat directly from the component to which one can attach any kind of heat dissipation system such as the present invention or those of the prior art. The connection pad will have a selected width which refers to the dimension of the pad usually greater than that of the component itself. Connections pads are standard in the art and one skilled in the art would be able to determine the width of the pad selected to be attached to a given electrical component.

As used herein a “heat dissipation system” is a plurality of structures designed to move heat generated by an electrical component from the heatsink connection pad to the ambient environment where circulating air will move the heat away from the dissipation system.

The electrical components of the present invention, such as an LED, will need electrical power to allow the device to operate. The component therefore must have 2 or more electrical leads from an AC or DC power supply to supply the selected component with the proper electrical power for operation. In one embodiment the LED is a greater than 1 W LED.

As used herein a “first solid heat dissipation structure” refers to a device made of solid metal such as Copper or other thermally conductive material such as one of many copper alloys or Aluminum or aluminum alloys known in the art, which is in direct thermally coupled contact with the heatsink connection pad. The length of the first structure is such that it is greater than the width of the connection pad. In one embodiment the first structure is columnar. In another embodiment the first structure is also an electrical lead from a power supply. The first structure may also provide structural support or pass through structural components to get to an ambient environment. In another embodiment there are a plurality of first structures surrounded by a single second structure. The solid first structure does not include vias or any channels designed for the purpose of heat dissipation.

As used herein the “second solid heat dissipation structure” refers to a structure also made of metal or other thermally conductive material, either the same or different from the first material. The second structure surrounds the first structure for a distance greater than the width of the connection pad as well, but while the first and second structures are thermally coupled, the second structure is not directly thermally coupled to the connection pad, only the first structure is. The second structure is positioned such that it can conduct heat energy from the second structure directly to the ambient environment. Accordingly, in one embodiment the length of the second structure is less than that of the first structure to allow for the fact that the second structure is not in contact with the connection pad. In one embodiment there is a thermal interface compound placed at the connection of the first and second structure to enhance the thermo couple connection between the two components. In another embodiment the second structure has wings to aid in heat exchange with the ambient environment. In another embodiment the second structure is columnar. In one embodiment the second structure is of a material with a lower thermal conductivity than the first structure, for example, when the first structure is made of Copper the second structure could be made of Aluminum. It is noted, however, that because the second structure surrounds the first, that it has a larger surface area which aids in thermal conductivity to the environment. While the second structure may have channels for running wires or other devices it essentially does not rely on vias or holes for heat dissipation and by solid means is essentially made of a solid heat dissipation material.

Methods of connecting thermo coupled material are well known, for example, utilizing the physical properties of the coefficient of thermal expansion of the two structures by relatively heating the second structure and cooling the first structure immediately prior to surrounding the first structure with the second, wherein after the two return to ambient conditions they will be snugly fitted together with a good thermal conduction connection.

Other embodiments of the invention include the use of fasteners in multiple fashions, machined features to utilize spring process in the system, interlocking features, metallurgical joining, or mechanical deformation (such as crimping and the like) to insure the best thermal conduction through a low resistance connection (contact).

The system of the present invention may further include a threaded interface between the first and second structure.

Even further the system may include a third component such as a mechanical fastener for the purpose of enhancing the contact pressure between the first and second structure. In some embodiments, the fastener can also provide a portion of the thermal path to an ambient environment. In yet another embodiment there is an electrical connection component such as a printed circuit board (PCB) which has a shaped cutout such that the electrical connection to the electrical component can be made while allowing passage of the first structure directly to the connection pad on the electrical component.

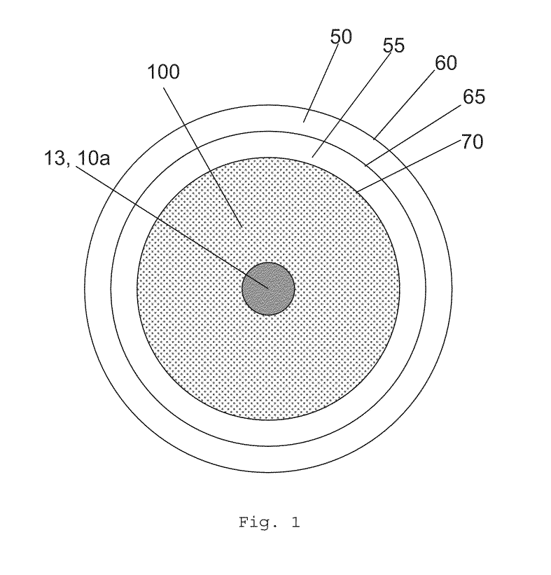

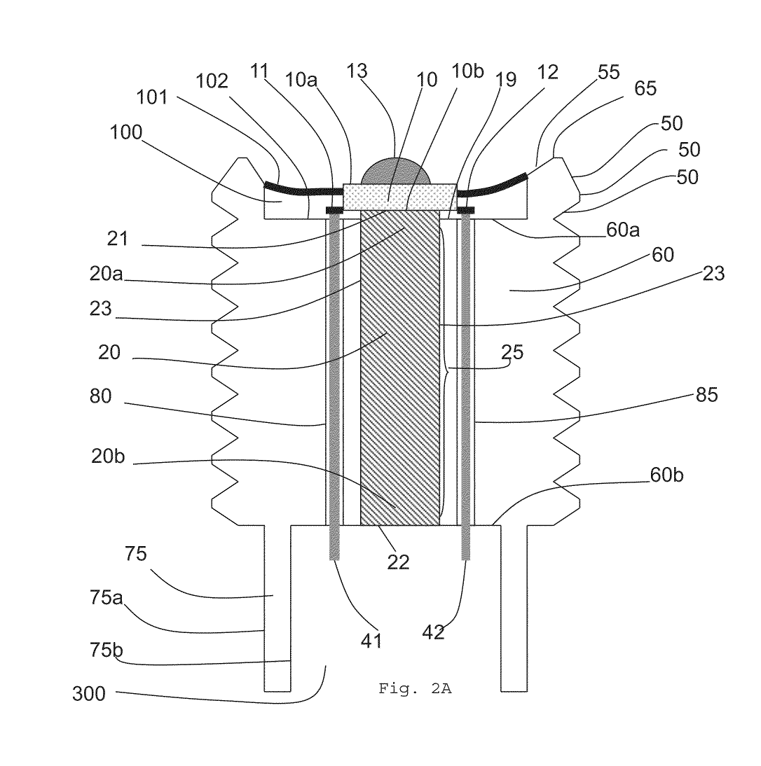

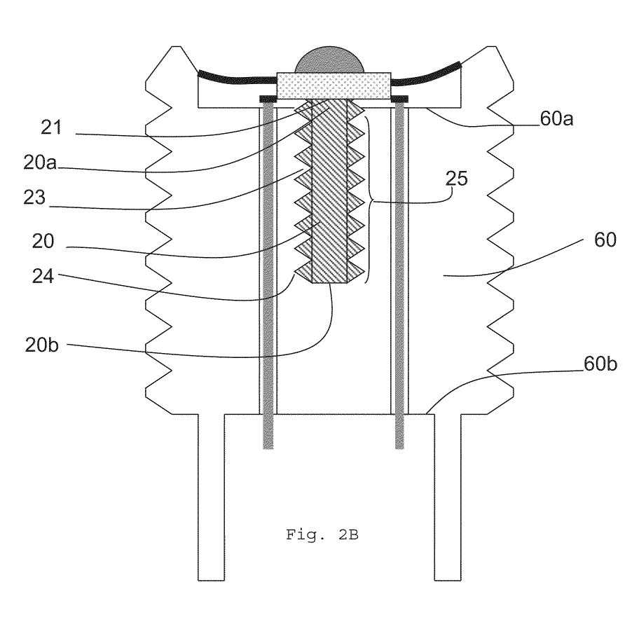

Now referring to the drawings, FIG. 1 is a top view of an embodiment of the present invention showing the relationship of the first and second dissipation structures. A high powered LED component with an attached lens 13, or top surface 10a where light is emitted is shown surrounded by a waterproofing sealant and non-conductive compound 100. The top surface of the sealant 100 is generally reflective in one embodiment. In other embodiments a reflective material is applied to the surface of sealant 100 to enhance reflectivity. FIG. 2A depicts the device in a side cut through view.

In FIG. 2A, 101 depicts the shaped surface of 100 which is for reflecting light energy in a desired direction. FIG. 1 shows the top view of the second structure 60. A surface of the second structure 60 is angled to act in conjunction with the shaped surface 101 to reflect light in a desired direction. The peak 65 of the second structure 60 is designed to extend approximately equal to or beyond the lens 13, to protect the component 10 (e.g. an LED) from damage should the assembly be physically impacted by another object. Second structure feature 70 is used for containment of the sealant 100, and defines an optimal volume and surface area of the sealant 100 while providing thickness for proper adhesion. Heat second structure fin surfaces 50 are depicted in FIG. 1 and further in FIG. 2A and transfer heat to ambient environment through conduction, convection, and radiation.

FIG. 2A shows details surrounding the electrical connections 11 and 12. The electrical connections 11 and 12 which power component 10 are soldered connections to the power supply wire leads 41 and 42. The wire leads 41 and 42 are routed through the second structure 60 through holes 80 and 85 respectively. The second structure 60 is part of a structural system which may include passthroughs for power/signal wiring. The interface 102, between the sealant 100 and the second structure top surface 60a, extends under the component 10 in the area of the electrical connections 11 and 12 and into the space 19 to provide electrical isolation between the leads and the second structure 60. In some embodiments, an insulating material, such as a plastic washer, can be applied in the space 19 to provide electrical isolation. In FIG. 2A, 21 represents the thermal connection, typically soldered for low thermal resistance, between the heatsink connection pad of 10 at 10b, and the first structure 20. Heat is moved from the device 10, through the heatsink connection pad on the bottom of the device 10b, through the thermal connection 21 to the top of the first structure 20a. Heat energy is then conducted through the first structure 20 to the opposite end 20b. The first structure 20 may have one of many or varying cross-section shapes. The design's intent is to have the least resistance to heat flow from the heatsink connection pad of the device 10 to 20b. The cross-sectional area of 20 is maintained at least as large as the heatsink connection pad area when possible. The primary heat conductor 20 has an aspect ratio such that the length, or distance from 20a to 20b, is greater than the width, or diameter of 21. This aspect ratio of greater than one, yields a large interface area 25 between the first structure 20 and the second structure 60. The interface 23 between the first structure 20 and the second structure 60 is designed to maximize heat transfer to 60 along the length of first structure 20 with the least resistance to ambient dissipation. The bottom of the first structure 22 may terminate against the second structure 60, or within a cavity 300 within the second structure 60. FIG. 2A shows the bottom of the first structure conductor 22 extending approximately equal to the length of second structure fin surfaces 50. Some embodiments of first structure 20 would include an oxygen-free Copper rod to provide a good soldering surface as well as excellent thermal conduction. With excellent thermal conduction properties, heat can be transported from first structure 20 through large interface area 25 to the surrounding second structure 60 with very low thermal resistance due to the high conductivity of first structure 20 with interface area 21 at the heat source and relatively large interface area 25 to the second structure 60. FIG. 2A shows a structural feature 75, on the second structure 60, which has an inner diameter 75b which forms a cavity wall for power supply components. Cavity 300 in some embodiments contains constant current power conditioning electronics for driving the LED with constant current. Cavity 300 may also contain excess length of wire leads 41 and 42 resulting from assembly operations. In some embodiments the power conditioning electronics or power supply components can use the second structure 60 to dispose of excess heat. Feature 75a is the outer diameter of structural feature 75 which is used for mounting other structural features. One embodiment of the invention uses an outer diameter for 75a of 1.05 inches to allow mating to standard polyvinylchloride (PVC) pipe fittings for rugged corrosion free handles.

The utilization of a highly thermal-conductive first structure 20 allows for packaging options not previously available for high power electrical components. In some embodiments first structure 20 is a ¼ inch diameter Oxygen-free Copper rod that has a length of one inch (25.4 mm) and mates to the heatsink connection pad of device 10 which is a CREE MC-E LED. This gives first structure 20 an aspect ratio of length to width of four. Embodiments of this invention have an aspect ratio of length to width of the first structure 20 of greater than one. Related to the length to width aspect ratio is the surface area ratio of the heat dissipation system. Shown in the table below is the effect of increasing the surface area ratio dramatically by increasing the length of the first structure 20. One embodiment of this invention uses a Cree MC-E LED with a 25 mm long, 6.35 mm diameter Copper 20 inserted into Aluminum second structure 60. The surface area ratio of 42 gives excellent conduction paths to ambient, resulting in low thermal resistance, and therefore a cooler and brighter LED.

| | LED | | Length of | | | |
|---|---|---|---|---|---|---|
| | Heat- | | First | Length | | |
| | sink | | Structure | to | | |
| | Con- | | inserted | Width | Radial | |
| | nection | Main | into | Aspect | Surface | Sur- |
| | Pad | Diam- | Second | Ratio | Area of | face |
| | Area | eter | structure | of | First | Area |
| LED Device | mm2 | mm | mm (20a | First | Structure | Ratio: |
| (10) | (21) | (20) | to 20b) | Structure | (25) | (25/21) |
| Cree: MC-E | 12 | 6.35 | 38.10 | 6.00 | 759.68 | 63 |
| Cree: MC-E | 12 | 6.35 | 25.40 | 4.00 | 506.45 | 42 |
| Cree: MC-E | 12 | 6.35 | 12.70 | 2.00 | 253.23 | 21 |
| Cree: MC-E | 12 | 6.35 | 6.35 | 1.00 | 126.61 | 11 |
| CREE: XP | 4.4 | 2.00 | 12.00 | 6.00 | 75.36 | 17 |
| CREE: XP | 4.4 | 2.00 | 8.00 | 4.00 | 50.24 | 11 |
| CREE: XP | 4.4 | 2.00 | 4.00 | 2.00 | 25.12 | 6 |
| CREE: XP | 4.4 | 2.00 | 2.00 | 1.00 | 12.56 | 3 |

In some embodiments of the invention, the first structure 20 could have a shape designed to match the electrical component 10 heatsink connection pad. In other embodiments, the first structure 20 could have a machined or formed end such that the thermal connection interface 21 is sized to match the electrical component 10. In other embodiments the first structure 20 will have a larger diameter/area than the thermal pad of the electrical component 10 in order to accommodate greater heat conduction through spreading as well as vertical transfer along the length of the first structure 20.

In some embodiments of the invention, the first structure 20 is a structural support for the electrical device 10. In other embodiments of the invention, the first structure 20 is not a structural component for the assembly and this is provided by second structure 60 and in some embodiments by water sealant 100.

In some embodiments of the invention, first structure 20 is also functioning as one of the power/signal leads that go to the electrical component 10. In some embodiments, the electrical device 10 does not have an isolated heatsink connection pad. As a result of integrating one of the leads 11 or 12 with the first structure 20, a larger diameter first structure 20 can be used without complicating assembly. The first structure 20 could then span the distance of the thermal pad of 10 as well as one of the leads 11 or 12, and thus simplify top side interconnections.

The heat dissipation system of this invention includes a second structure 60. Heat energy flows from the electrical component 10 through the heatsink connection pad interface 21 to first structure 20 through the interface area 25 and into the second structure 60. From second structure 60, the heat energy is dissipated to ambient at the interface 50 which may or may not have a special surface area increasing features to promote faster dissipation.

In some embodiments of the invention, material advantages can be gained. As Oxygen-free Copper is an optimal choice for first structure 20, aluminum is an optimal choice for second structure 60. By making the second structure 60 out of Aluminum, cost is reduced. The first structure 20 is providing optimal heat transfer away from the electrical component 10, and providing a large surface area contact to second structure 60. The length to width aspect ratio in some embodiments of the second surface is between one and ten. Many different combinations of materials can be used. It is most beneficial to have the lowest thermal resistance material as the first structure 20 and the higher thermal resistance material for the second structure 60. This combination utilizes the advantages of heat flow from the device 10 through the first structure 20 to the furthest reaches of the second structure 60 with minimal resistance which is beneficial for the electrical device 10.

In some embodiments of the invention in FIG. 2A, advantages are gained as the second structure 60 provides the structural support for the electrical component 10. In some embodiments of the invention in FIG. 2A, second structure 60 provides the structural support for the power supply and power conditioning components in cavity 300 formed by features such as 75. The second structure 60 can also form the bulk of a standalone structure, such as a handheld lighting device. In other embodiments, the structure provided by the second structure 60 is mated to other structures by designed features 75a such as a machined diameter to provide coupling to other structures by designed features 75a such as a machined diameter to provide coupling to other structures which provide aesthetic qualities or other functional structural features such as light-weight handles, buoyant handles, or different size structural component cavities.

In some embodiments of the invention in FIG. 1 and FIG. 2A, structural features such as 55 are employed to provide physical, mechanical, and electrical shorting protection for electrical component 10 and to provide a cavity for sealants to protect the component 10. In some embodiments of the invention, a waterproof sealant 100 is applied in the cavity to provide underwater use capability as well as light reflection/direction properties.

In some embodiments of the invention, the second structure 60 is surface treated, such as with an anodizing process, to provide saltwater corrosion protection at the interface to ambient 50.

In further discussions regarding the heat dissipation systems of this invention, the structural discussions in the previous paragraphs referencing numbered structural features in FIG. 1 and FIG. 2A will apply as well to all included figures showing a second structure 60.

In order to achieve best thermal transfer between the interface 25, a close fit between the first structure 20 and the second structure 60 is needed. In some embodiments of the invention, this fit can be achieved with a precise machining of the piece-parts.

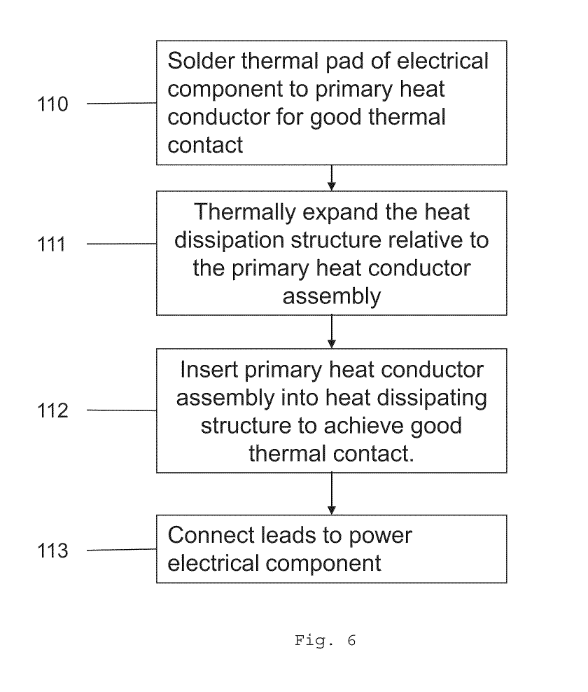

In some embodiments of the invention, an improved fit between first structure 20 and second structure 60 can be obtained by using a method to take advantage of the CTE of the materials. If the second structure 60 is thermally expanded by heating, a slight but measureable gain in inner diameter is achieved. Correspondingly, the first structure 20 can be cooled and a slight reduction in outer diameter will be realized. If the two pieces are assembled when second structure 60 is thermally expanded and first structure 20 is thermally contracted, then once the temperatures have reached equilibrium at interface 25, the fit will be improved (i.e. more closely coupled) and heat transfer will be more efficient. This method is shown in FIG. 6.

In some embodiments of the invention, the thermal interface 25 can be enhanced with the use of a thermal compound for conducting heat across the interface 25. Thermal compound can range from thermal grease specially formulated for high heat conductive properties to any fill material that displaces air gaps.

In some embodiments of the invention, a mechanical fastener can be used to ensure a high conductive interface 25 is maintained between the first structure 20 and the second structure 60. In some embodiments a threaded-fastener provides additional contact surface area to the first structure 20 and acts as a thermal conductor to the second structure 60.

In some embodiments of the invention, metallurgical bonding by soldering, brazing, welding, chemical bonding, etc. is used to ensure direct thermal connection between the first structure 20 and the second structure 60. In other embodiments of the invention, deformation processes (such as crimping) depicted can ensure good thermal connection at interface 25. During metal deformation processing such as crimping, surface roughness or surface features of surfaces coming into contact can be tuned to provide excellent thermal results.

In some embodiments of the invention, as shown in FIG. 2B, the first structure 20 is threaded 24 to mate with second structure 60 to form a threaded interface 23 which greatly increases the surface area of 25 as compared to non-threaded versions. Torque applied to threads assures that good thermal contact is maintained.

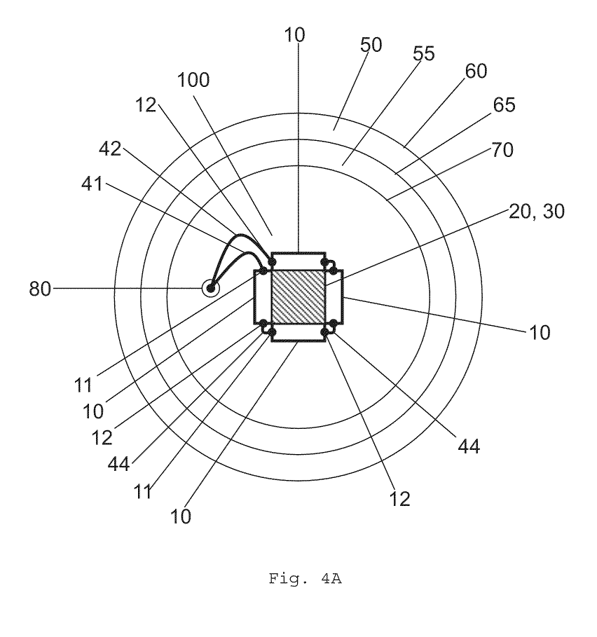

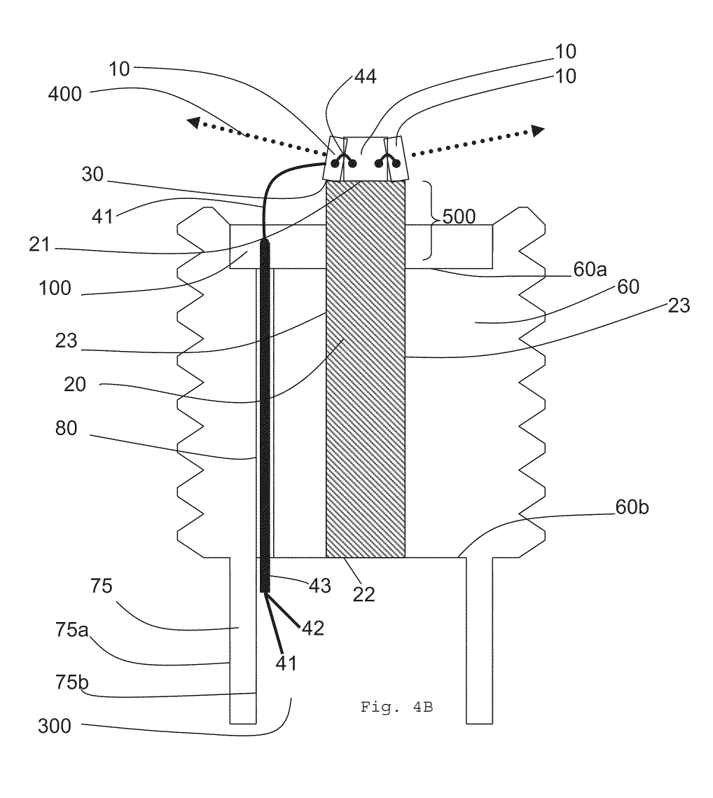

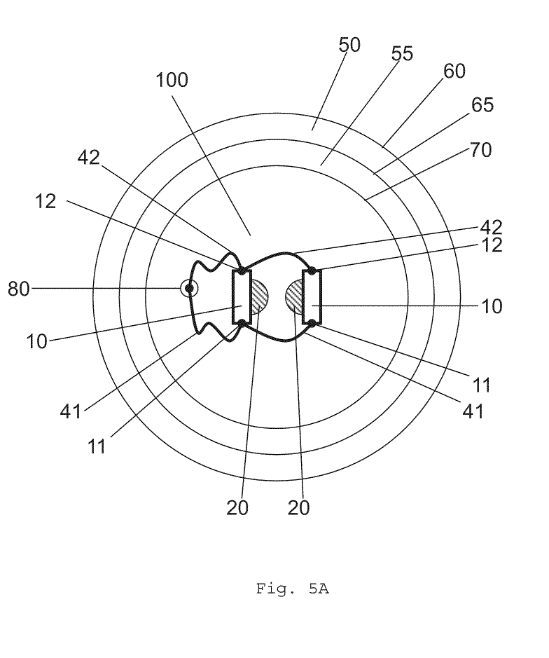

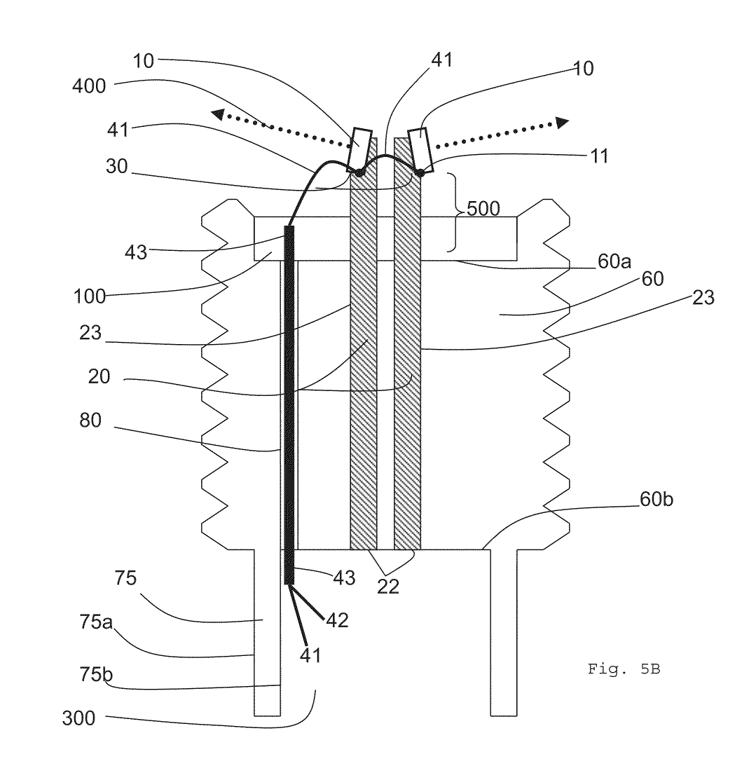

In some embodiments of the invention as depicted in FIGS. 4A and 4B, there can be multiple electrical components 10 per first structure 20. As well, there can be multiple electronic components 10 on multiple first structure 20 per heat dissipation structure as shown in FIGS. 5A and 5B. As more wattage is applied to drive more electrical components, the more critical the thermal resistance of the system for optimal component performance. The LEDs 10 can be angled by placing on a shaped end 30 of the first structure 20 such that the radiant flux 400 is directed as desired. FIGS. 4A and 4B show an embodiment with multiple LEDs 10 on a single first structure 10 wired in series. FIGS. 5A and 5B show an embodiment with multiple LEDs 10 on multiple first structures 20 wired in parallel. In other embodiments, the LEDs can be connected in a series, parallel, or a combination of series/parallel by the use of connecting wires 44 to arrangements of anodes 41 and cathodes 42 connections. In some embodiments the series and parallel connections can be made and powered in cavity 300. The distance 500 from the component heatsink thermal interface 21 to the top of the first structure 60a can be significant if desired due to the use of a highly thermally conductive first structure 20 allowing design flexibility with this embodiment.

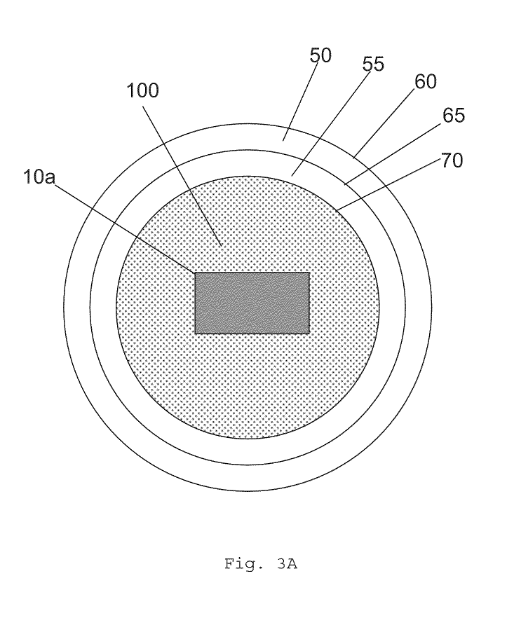

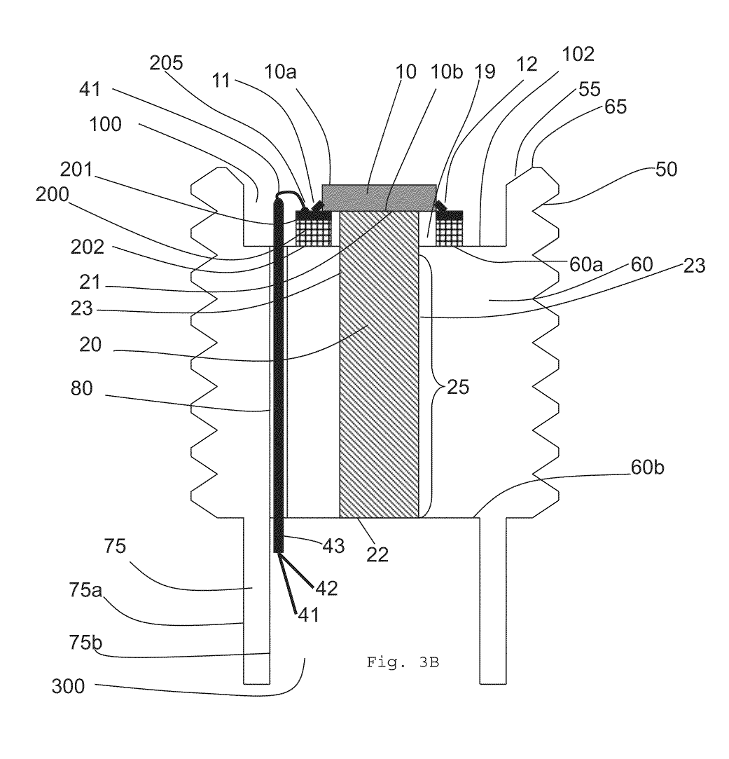

In some embodiments as shown in FIG. 3B, a PCB/PWB/MCPCB 200 is an electrical-connection-component that provides the electrical connections to the electronic device and in some embodiments provide a surface for protecting and in some embodiments sealing structural and electrical components for waterproof operation. FIG. 3A shows an embodiment with sealant 100 surrounding the electrical device 10 except for the top surface 10a. FIG. 3B shows an embodiment incorporating a PCB/PWB/MCPCB to make electrical connections through the top traces 201 of the PCB/PWB/MCPCB to the anode and cathode leads, 11 and 12, of the device 10. Power is depicted as being supplied in this embodiment by a power supply cable 43 containing power leads 41 and 42 passing through a hole 80 in the second structure 60. By incorporating a PCB/PWB/MCPCB to route power to the component or components, an increased gap 19 is created. Given the low thermal resistance of the primary heat conductor 20, this extra distance from the heat dissipation structure is easily tolerated without detrimental heating effects. In some embodiments, a sealant 100 is not used if protection from the environment is not a concern.

In some embodiments of the invention, the thermal interface 25 between the first structure 20 and the second structure 60 is maintained by spring force from the second structure 60. By designing the second structure 60 such that it may be flexed with a bending action open to the cavity enough to slide the first structure 20 into the opening so that when the bending moment is removed from second structure 60, the increased opening will close and provide a constant clamping spring force onto first structure 20 maintaining a good thermal interface 25. The second structure 60 in this embodiment may be made up of several pieces as it can be envisioned that one or more of the clamping pieces could be locked or installed during the flexing moment to aid assembly and simplify the insertion of first structure 20. In some embodiments of this approach, it can be envisioned that post insertion of the first structure 20, that the second structure 60 is flexed or has a moment applied to create a clamping force on the thermal interface 25 assuring good thermal transfer.

FIG. 6 is a flow chart of an embodiment the method of making and utilizing the present invention. A thermal pad of an electrical component is soldered to a primary heat conductor 110. The heat dissipation structure is expanded relative to the primary heat conductor assembly 111. Next, the primary heat conductor assembly is inserted into the heat dissipating structure 112. Electrical leads 113 are connected to the electrical component and provide heat dissipation.

What is claimed is:

1. An electrical component having a heatsink connection pad which has a selected width in direct contact with the electrical component, which has electrical leads from a power supply to the component to supply the component electrical power and having a heat dissipation system comprising:
a) a first solid heat dissipation structure, thermally coupled directly to the connection pad having a length greater than the connection pad width;
b) a second solid heat dissipation structure surrounding and thermally coupled to the first structure for a distance greater than the width of the connection pad but which is not coupled to the connection pad and positioned the conduct heat energy to an ambient environment.

2. A component according to claim 1 wherein the electrical component is one or more LEDs.

3. A component according to claim 1 wherein the first and second structures are constructed of a solid metal.

4. A component according to claim 1 wherein the thermocouple connection between the first and second structure has a thermal interface compound to enhance the thermo couple connection.

5. A component according to claim 1 wherein the first structure acts as one of the electrical leads.

6. A component according to claim 1 wherein the first structure has a length to width ration of between about 1 to 4.

7. A component according to claim 1 wherein the first structure has a lower thermal resistance than the second structure.
